(19) United States
(12) Patent Application Publication
(10) Pub. No.: US 2026/0135546 A1
(43) Pub. Date: May 14, 2026

(54) EFFICIENT WINDOW GENERATION

(71) Applicant: SKYWORKS SOLUTIONS, INC., Irvine, CA (US)

(72) Inventors: Amit Kumar, Portland, OR (US); David Lamb, Portland, OR (US); Arman Samimi-dehkordi, Mountain View, CA (US)

(21) Appl. No.: 19/361,093

(22) Filed: Oct. 17, 2025

Related U.S. Application Data
(60) Provisional application No. 63/711,250, filed on Oct. 24, 2024.

(51) Int. Cl. H03K 5/13

(52) U.S. Cl. CPC H03K 5/13

(57) ABSTRACT

A window function generating system is presented herein. The system includes a first node; a second node; an integrator portion coupled to the first node; a differentiator portion coupled to the second node; and a rate adjustor coupled to the integrator portion and to the differentiator portion. The system also includes a multiplier configured to receive an input signal from the input node and a window function signal from the second node and to produce an output signal based on the input signal and window function signal.

### CROSS REFERENCE TO RELATED APPLICATIONS

This application claims priority, under 35 U.S.C. § 119, to U.S. Provisional Patent Application 63/711,250, titled EFFICIENT WINDOW GENERATION, filed on Oct. 24, 2024, said application being hereby incorporated by reference in its entirety for all purposes.

### BACKGROUND

### 1. Field of the Disclosure

At least one example in accordance with the present disclosure relates generally to window function generation in hardware.

### 2. Discussion of Related Art

Window functions are well-understood in digital signal processing. Most window functions are generated using complex and large circuits that may use substantial amounts of power and/or memory, and which are generally inefficient.

### SUMMARY

According to at least one aspect of the present disclosure, window function generating system is presented, comprising: an input node; an output node; a first summing node coupled to the input node, a first delay, and a rate adjustor; a second summing node coupled to the output node, a second delay, and the rate adjustor.

In some examples, the first delay is coupled to the first summing node at an input and an output of the first delay. In some examples, the second delay is coupled to the second summing node at an input and an output of the second delay.

According to at least one aspect of the present disclosure, window function generating system is presented, comprising: a first node; a second node; an integrator portion; a differentiator portion; and a rate adjustor.

In some examples, the first node is coupled to the integrator portion and the integrator portion is coupled to the rate adjustor. In some examples, the second node is coupled to the differentiator portion and the differentiator portion is coupled to the rate adjustor. In some examples, the second node is coupled to the integrator portion. In some examples, the first node is coupled to the differentiator portion. In some examples, the integrator portion includes a plurality of integrator elements, each integrator element including a respective summing node and a respective delay, wherein the respective summing node of an integrator element is coupled to the respective delay of the integrator element at an input and an output of the delay. In some examples, the respective summing node of the integrator element is coupled to at least one other summing node of a different integrator element. In some examples, at least one summing node of the integrator portion is coupled to the rate adjustor. In some examples, the differentiator portion includes a plurality of differentiator elements, each differentiator element including a respective summing node and a respective delay, the respective delay of a differentiator element is coupled to the respective summing node of the differentiator element at an input of the summing node. In some examples, the respective summing node of the differentiator element is coupled to at least one other summing node of a different differentiator element. In some examples, at least one summing node of the differentiator portion is coupled to the rate adjustor. In some examples, the first node is one of an output or an input, and the second node is the other of the output or input.

According to at least one aspect of the present disclosure, window function generating system is presented, comprising an input generator; an integrator portion coupled to the input generator; and an output coupled to the integrator portion.

In some examples, the input generator is configured to provide a sequence of values to the integrator portion, the sequence of values being a predetermined sequence corresponding to −1, 0, and 1. In some examples, values of the sequence of values correspond to respective voltages, −1 corresponding to a low voltage, 0 corresponding to a middle voltage, and 1 corresponding to a high voltage. In some examples the integrator portion includes at least a first summing node coupled to a first delay at an input and an output of the first delay. In some examples, the integrator portion includes at least a second summing node coupled to a second delay at an input and an output of the second delay. In some examples, at least one summing node of the integrator portion is coupled to a multiplier, and at least one summing node of the integrator portion is coupled to the input generator. In some examples, the at least one summing node coupled to the multiplier is different from the at least one summing node coupled to the input generator. In some examples, the input generator includes a multiplexer configured to select between values of the sequence of values, and a select generator configured to control the multiplexer to determine which value of the sequence of values is provided to the integrator portion. In some examples, the system further comprises a mute control coupled to delay lines of the integrator portion and configured to provide a signal to the input generator to force the input generator to provide a 0 to the integrator portion. In some examples, the system further comprises a multiplier and a target signal input, the target signal input being coupled to the multiplier and configured to provide a target signal to the multiplier, and the multiplier being configured to multiply an output of the integrator with the target signal to produce a processed signal.

### BRIEF DESCRIPTION OF THE DRAWINGS

Various aspects of at least one embodiment are discussed below with reference to the accompanying figures, which are not intended to be drawn to scale. The figures are included to provide an illustration and a further understanding of the various aspects and embodiments, and are incorporated in and constitute a part of this specification, but are not intended as a definition of the limits of any particular embodiment. The drawings, together with the remainder of the specification, serve to explain principles and operations of the described and claimed aspects and embodiments. In the figures, each identical or nearly identical component that is illustrated in various figures is represented by a like numeral. For purposes of clarity, not every component may be labeled in every figure. In the figures:

FIG. 1A illustrates a CIC filter according to an example;

FIG. 1B illustrates a CIC filter according to an example;

FIG. 2 illustrates a CIC filter according to an example;

FIG. 3 illustrates graphs of filter responses according to an example;

FIG. 4 illustrates a window function generator according to an example; and

FIG. 5 illustrates a window function generator according to an example.

### DETAILED DESCRIPTION

Aspects of this invention relate generally to generating window functions for use in signal processing or in any other application that relies on window functions. In particular, methods of efficiently generating window functions of any order and with any characteristics (or close approximations thereto) are provided.

Window functions are mathematical functions that are typically zero-valued outside of a chosen interval or intervals. Window functions have multiple uses, including in filter design, spectral analysis, beamforming, signal processing (e.g., digital signal processing), and so forth. Window functions have a multitude of uses that are well-known in the art. For example, window functions can be used to provide a weighted, finite portion of a signal for the purpose of performing Fourier transformations (e.g., the Discrete Fourier Transform). When a window function is used in this way during a Discrete Fourier transform, the window function may improve certain features of the transformation, for example, by reducing spectral leakage.

A large number of window functions exist, including the Hann and Hamming windows, the Blackman window, the Blackman-Harris window, and so forth. Each of these window functions has its own unique characteristics and features. Depending on a given application or problem, one window function may be more desirable than another to use.

These window functions require at least some hardware, and often software as well, to implement. Because some window functions can be quite complex, the hardware requirements may be substantial. Consider, for example, the Hann function, used to generate a Hann window, which is shown in equations (1) and (2) below:

$$w [ n ] = L \cdot {w}_{0} ( \frac{L}{N} ( n - N / 2 ) ) \qquad ( 1 )$$

$$w [ n ] = \frac{1}{2} ( 1 - cos ( \frac{2 π n}{N} ) ) = {sin}^{2} ( \frac{π n}{N} ) \qquad ( 2 )$$

As can be seen from equations (1) and (2), the Hann function contains trigonometric operations. Other window functions may also contain similar operations, which may be difficult to efficiently generate in hardware.

In some examples, hardware can have a large memory to store pre-computed values of window functions for different lengths, or a power microcontroller or Digital-Signal-Processing (DSP) core that can generate the values on the fly. For example, such circuits can include read-only memory (ROM) or random-access memory (RAM) that can contain hundreds or thousands of coefficients that may be accessed at any time to generate a given window function.

In other cases, the hardware is constrained by power and/or available area. Difficulties can arise in certain situations, such as when the available circuit area is limited. When circuit area is sufficiently limited, storing large numbers of coefficients in memory becomes expensive or impossible, and complex generation circuits that require large amounts of space and/or power cannot be effectively deployed.

Aspects of this disclosure relate to providing for efficient generation of window functions with a low hardware cost through the use of Cascaded-Integrator-Comb (CIC) filters. The techniques disclosed herein are elegant, simple, flexible, regular and modular, and trivial to design once the technique is understood.

To use the CIC filter to generate a window function, the CIC filter may be provided with an impulse at an input. The CIC filter will then generate an impulse response at its output. That impulse response may be multiplied with a target signal, where the target signal is intended for processing. Because the impulse response of the CIC filter generates a signal that is zero except within a given window, the impulse response of the CIC filter may be used as a window function. Further details are provided below.

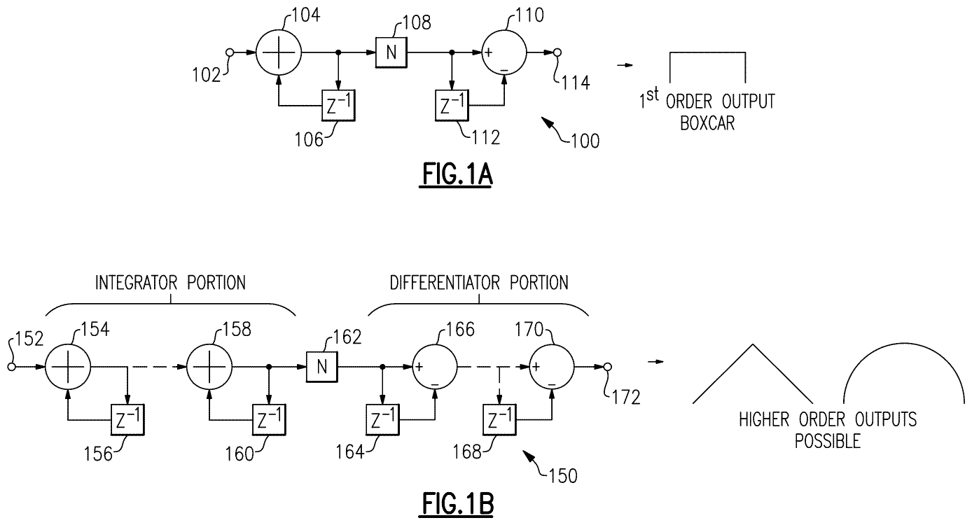

FIG. 1A illustrates a first-order CIC filter 100 according to an example. The first-order CIC filter 100 includes an input 102, a first summing node 104, a first delay 106, a rate adjustor 108, a second summing node 110, a second delay 112, and an output 114.

The first-order CIC filter 100 is built without any coefficient inputs for any N, as will be discussed below. When an impulse (e.g., a signal such as 100000 . . . ) is fed into the input 102 of the filter 100, a boxcar output with length proportional to N is produced, which may correspond to a convolution of an impulse with the impulse response function of the filter. N represents a reduction in rate (e.g., a decimation) of the input signal.

The input 102 is coupled to the first summing node 104. The first summing node 104 is coupled to the first delay 106 and the rate adjustor 108. The first delay 106 is coupled to the first summing node 104. The rate adjustor 108 is coupled to the second summing node 110 and the second delay 112. The second delay 112 is coupled to the second summing node 110. The second summing node 110 is coupled to the output 114.

In some examples of operation, an impulse is provided at the input 102. The impulse is then provided to the summing node 104. The summing node 104 provides an output that is the sum of the input and a first delayed signal from the first delay 106. The output of the summing node 104 is provided to the first delay 106 and the rate adjustor 108. The first delay 106 receives the output of the first summing node 104 and feeds that output back to the first summing node as the first delayed signal after a predetermined or configurable period of time. Thus, the output of the first summing node 104 is ultimately based on the current input (at the input 102) and a feedback signal (the first delayed signal) from the first delay 106.

The rate adjustor 108 receives the output of the first summing node 104 and adjusts the rate of that output. In many examples, the rate adjustor 108 is a decimator (e.g., it reduces the rate of the output of the first summing node 104). The rate adjustor 108 then provides the rate-adjusted signal to the second delay 112 and the second summing node 110.

The second delay 112 delays the rate-adjusted signal by a predetermined or configurable period of time to produce a second delayed signal. The second delay 112 then provides the second delayed signal to the second summing node 110. The second summing node 110 subtracts the second delayed signal from the rate-adjusted signal to produce the output signal, and provides the output signal to the output 114.

FIG. 1B illustrates an R^{th} order CIC filter 150 according to an example. The filter 150 includes an input 152, a first summing node 154, a first delay 156, a second summing node 158, a second delay 160, a rate adjustor 162, a third delay 164, a third summing node 166, a fourth delay 168, a fourth summing node 170, and an output 172. Furthermore, the filter 150 may include an arbitrary number of additional summing nodes and delays. In general, the number of summing nodes and delays on both sides of the rate adjustor 162 is equal. In this particular example, the total number of summing node and delay pairs on a given side of the rate adjustor 162 equals the order of the filter 150. Thus, as illustrated, the filter 150 is at minimum a second order filter, though it may be of any desired order.

The input 152 is coupled to the first summing node 154. The first summing node 154 is coupled to the first delay 156 and to a next summing node. In the case of a second order filter, the next summing node would be the second summing node 158. In the case of a filter of order greater than second, the next summing node would be a different summing node from any of the first, second, third, or fourth summing nodes 154, 158, 166, 170. The first delay 156 is coupled to the first summing node 154. The second summing node 158 is coupled to the second delay 160 and to the rate adjustor 162. The second delay 160 is coupled to the second summing node 158. The rate adjustor 162 is coupled to the third delay 164 and the third summing node 166. The third delay 164 is coupled to the third summing node 166. The third summing node 166 is coupled to a next summing node and a next delay node. If the case of a second order filter, the next summing node would be the fourth summing node 170, and the next delay would be the fourth delay 168. However, in the case of a filter of order greater than second, the next summing node would be other than the first, second, third, or fourth summing nodes 154, 158, 166, 170, and the next delay would be other than the first, second, third, or fourth delays 156, 160, 164, 168.

The operation of the R^{th} order CIC filter 150 is generally the same as that of the first order CIC filter 100, except that the R^{th} order CIC filter 150 has additional summing nodes and delays that process the input signal prior to generation of the output signal.

In general, an input signal is provided at the input 152 to the first summing node 154. The first summing node 154 sums the input signal with a first delayed signal from the first delay 156, where the first delayed signal is a version of the sum of the output of the first summing node 154 and the first delayed signal that has been delayed for a predetermined or configurable amount of time. The output of the first summing node 154 is then processed by the next summing node and next delay in a similar manner (e.g., the sum of the feedback of a delayed version of the output of the next summing node and the input into the next summing node). This process of summing inputs with delayed signals is repeated an arbitrary number of times, until the resulting signal is at least processed by the second summing node 158 and the second delay 160. The output of the second summing node 158 is provided to the rate adjustor 162, which increases or decreases the rate of the signal. In many cases, the rate adjustor 162 is a decimator.

The rate adjustor 162 then provides the rate-adjusted signal to the third delay 164 and third summing node 166. The third delay 164 delays the rate-adjusted signal by a predetermined and/or configurable amount of time, before providing the rate-adjusted signal to the third summing node 166 as a third delayed signal. The third summing node 166 subtracts the third delayed signal from the (present version of) the rate-adjusted signal to produce an output signal that is then provided to the next summing node and delay. The next summing node and delay carry out the same operations as the third summing node 166 and the third delay 164, but use the output of the third summing node 166 in place of the rate-adjusted signal. A similar process repeats for each subsequent summing node and delay, where the output of the previous summing node feeds the input of the next summing node and delay. This process ends when the fourth summing node 170 receives the output of the penultimate summing node and subtracts the fourth delayed signal from the output of the penultimate summing node. The fourth delayed signal is generated by the fourth delay 168 as a version of the output of the penultimate summing node that is delayed by a predetermined and/or configurable amount of time. The fourth summing node 170 then provides its output signal to the output 172.

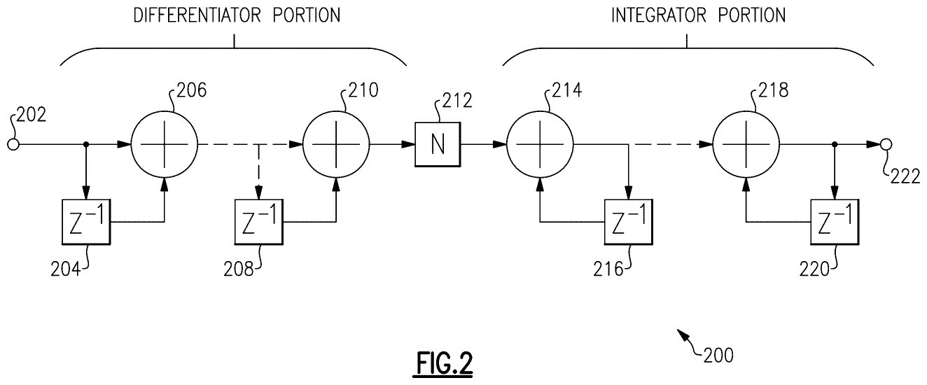

CIC filters may also be used as interpolators of R^{th} order, where R is the number of summing nodes in the filter plus one. FIG. 2 illustrates an R^{th} order CIC filter 200 configured as an interpolator according to an example.

The filter 200 includes an input 202, a first delay 204, a first summing node 206, a second delay 208, a second summing node 210, a rate adjustor 212, a third summing node 214, a third delay 216, a fourth summing node 218, a fourth delay 220, and an output 222.

The input 202 is coupled to the first delay 204 and first summing node 206. The first delay 204 is coupled to the first summing node 206. The first summing node 206 is coupled to a next summing node and a next delay unless the filter is first order, in which case the first summing node 206 is coupled directly to the rate adjustor 212, and the second summing node 210 and second delay 208 are omitted. If the filter 200 is second order, the first summing node 206 is coupled to the second delay 208 and the second summing node 210. If the filter 200 has order greater than two, than the next summing node and next delay are other than the first, second, third, or fourth summing nodes 206, 210, 214, 218 or delays 204, 208, 216, 220.

For order of two or greater, the second delay 208 is coupled to the second summing node 210, and the second summing node is coupled to the rate adjustor 212. The second summing node 210 and second delay 208 are also coupled to preceding summing nodes and delays: for example, in the case of a second order filter, the first summing node 206 is coupled to the second delay 208 and second summing node 210.

The rate adjustor 212 is coupled to the third summing node 214. The third summing node 214 is coupled to the third delay 216 and to a next summing node. The next summing node would, in turn, be coupled to a next delay and, possibly, yet another summing node, and so forth. In the case of a filter of order greater than three, the next summing node and next delay are other than the first, second, third, or fourth summing nodes 206, 210, 214, 218 or delays 104, 108, 216, 220. In the case of a second order filter, the next summing node and delay would be the fourth summing node 218 and fourth delay 220. The fourth summing node 218 is coupled to a preceding summing node and to the fourth delay 220, as well as the output 222. The fourth delay 220 is coupled to the fourth summing node 218.

The filter 200 works in a similar manner to the filters 100, 150 of FIGS. 1A and 1B. In some examples, the rate adjustor 212 increases the rate of the signal it receives as an input instead of decimating (e.g., decreasing) the rate.

To briefly summarize the operation of the filter 200, an input signal is received at the input 202 and provided to the first delay 204 and first summing node 206. The first delay delays the input signal by a predetermined or configurable amount of time and provides that delayed input signal to the first summing node 206 as a first delayed signal. The summing node sums the first delayed signal and the input signal and provides the result to the next delay and next summing node. The next delay and next summing node similarly delay and sum the signal from the first summing node 206, before passing it on to the next delay and summing node in the sequence. The sequence ends when the second delay 208 and second summing node 210 receive the resulting signal from the preceding delays and summing nodes. The second delay 208 delays the resulting signal and provides the delayed resulting signal to the second summing node 210 as a second delayed signal. The second summing node 210 then sums the resulting signal and the second delayed signal and provides that summed signal to the rate adjustor 212.

The rate adjustor 212 increases the rate of the signal from the second summing node 210 and provides the resulting rate-adjusted signal to the third summing node 214.

The third summing node 214 sums the rate-adjusted signal with a third delayed signal from the third delay 216, and provides that summed signal as an output signal to the next summing node and the third delay 216. The third delay 216 delays that output signal by a predetermined or configurable amount of time and provides the resulting third delayed signal to the third summing node 214. Various additional summing nodes and delays repeat this process, using the output of the preceding summing node as their input, until the sequence ends with the fourth summing node 218. The fourth summing node 218 receives the resulting signal from the immediately preceding summing node in the sequence and sums that signal together with a fourth delayed signal from the fourth delay 220. The fourth summing node 218 then provides its output as an output signal to the output 222 and to the fourth delay 220. The fourth delay 220 delays the output signal by a predetermined or set period of time, and provides the resulting fourth delayed signal to the fourth summing node 218.

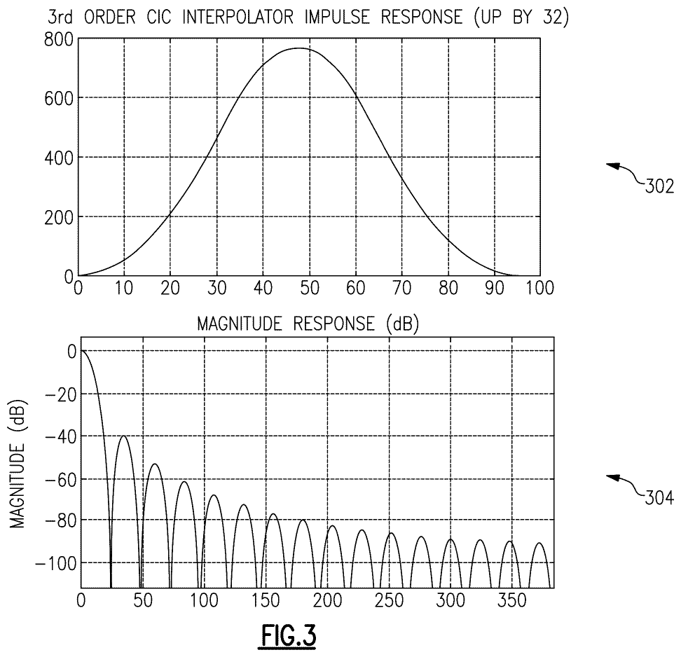

FIG. 3 illustrates two graphs, a first graph 302 and a second graph 304, according to an example. These graphs 302, 304 reflect potential impulse and magnitude responses of the CIC filter 200 when the CIC filter 200 is configured as a third order filter, according to an example. The first graph 302 illustrates the frequency response according to an example. The second graph 304 illustrates the magnitude response according to an example.

In graph 302, the x-axis indicates time and the y-axis indicates amplitude of the impulse response. In graph 304, the x-axis indicates frequency and the y-axis indicates attenuation and/or gain. As can be seen in graph 302, the impulse response of the R^{th} order CIC filter 200, configured to operate as a third order filter, increases from zero over time, reaches a maximum, and then decreases back to zero in a roughly parabolic manner. Likewise, the magnitude response, as shown in graph 304, illustrates that the attenuation provided by the filter 200 increases rapidly from 0 dB to −40 dB and onward, eventually reaching approximately −90 dB in this example. In some examples, the maximum value of the impulse response may be a power of two.

The impulse response of the filter 200 may be used as a window function, since the impulse response exists and changes over time. For example, the impulse response shown in graph 302 is similar to a Hann window. That is, the impulse response in graph 302 is sufficiently similar to a Hann window to be used in place of a Hann window in most applications. Additional adjustments to the filter 200 can make the impulse response more or less similar to a Hann window, or many other window functions, as desired.

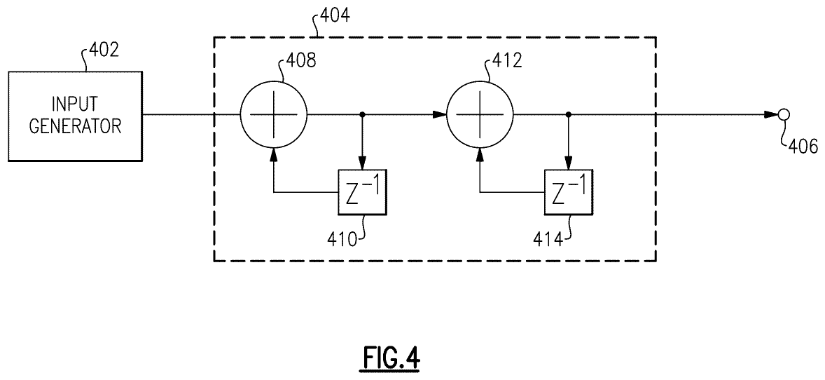

FIG. 4 illustrates a window function generator 400 according to an example. The window function generator 400 includes an input generator 402, an integrator portion 404, and an output 406. The integrator portion 404 includes one or more summing nodes and one or more delays. In this example, the integrator portion 404 includes a first summing node 408, a first delay 410, a second summing node 412, and a second delay 414.

The input generator 402 is coupled to the integrator portion 404 via the first summing node 408. The first summing node 408 is coupled to the first delay 410 and to the second summing node 412. The first delay 410 is coupled to the first summing node 408. The second summing node 412 is coupled to the second delay 414 and the output 406. The second delay 414 is coupled to the second summing node 412.

While, in this example, only two summing nodes and delays are shown, any number of summing node and delay pairs may be included in series between the input generator 402 and the output 406, according to the order desired for the CIC filter, as will be discussed below.

The input generator 402 and integrator portion 404 operates as a CIC filter, such as those described above. However, because the impulse response of the CIC filter is being used as a window function, there is no need to filter an input signal through the differentiator and the rate adjustor portions of the filter. Thus, the input to the CIC filter is known ahead of time. Likewise, the rate adjustment provided by the rate adjustor is known ahead of time. As a result, the input generator 402 may simply generate a sequence of voltages (generally high, middle, and/or low, e.g., values corresponding to 1, 0, or −1) that correspond to an impulse that has been rate adjusted. That is, using FIG. 2 for reference, the input generator 402 may simply output a sequence of voltages that correspond to what would happen if an impulse was processed by the portions of the filter 200 of FIG. 2 from the input 202 to the rate adjustor 212.

The integrator portion 404 of the window function generator 400 operates identically to the parts of the filter 200 in FIG. 2 between (and including) the first summing node 214 through to the output 222. That is, the input generator 402 provides a signal to the first summing node 408. The first summing node then sums that first input signal with a first delayed signal produced by the first delay 410 to produce a second input signal, and then provides the second input signal to the first delay 410 and the second summing node 412. The first delay 410 delays the second input signal by some amount (predetermined or configurable) to generate the first delayed signal. The second summing node 412 then sums the second input signal with a second delayed signal produced by the second delay 414 to produce the output signal. The second summing node 412 provides the output signal to the second delay 414 and to the output 406. The second delay delays the output signal by some amount (predetermined or configurable) to produce the second delayed signal.

The output signal will be the impulse response of the window function generator 402 (and therefore the “virtual” CIC filter formed by the input generator 402 and the integrator portion 404). The output 406 may provide the output to a multiplier node or similar node, where the output signal is combined (e.g., multiplied) together with a target signal that is being processed using the window function (for example, for performing a Fourier Transformation).

As mentioned above, the window function generator 400 (and the filters 100, 150, 200) may be manipulated in various ways to change the impulse response and/or magnitude response of the system. Manipulations may include changing the length of delays, increasing or decreasing the rate adjustment, and so forth. Some of these possible changes are discussed below.

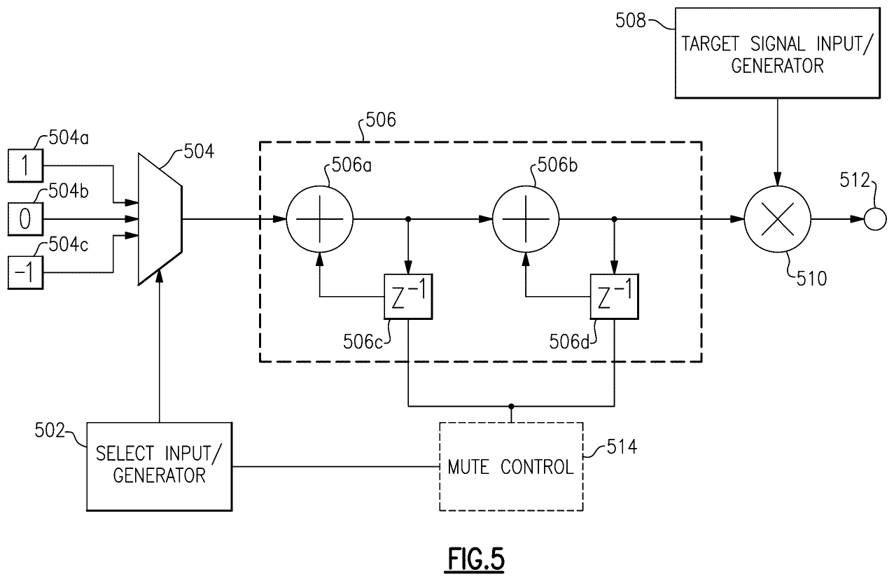

FIG. 5 illustrates an audio processing system 500 according to an example. The system 500 includes a select input 502, a multiplexer 504, a first multiplexer input 504a, a second multiplexer input 504b, and a third multiplexer input 504c, an integrator portion 506 having a first summing node 506a, a second summing node 506b, a first delay 506c, and a second delay 506d, a target signal input 508, a multiplier 510, and an output 512. A mute control 514 is also shown. The mute control 514 is optional.

The select input 502 is coupled to a control connection of the multiplexer 504. The multiplexer inputs 504a, 504b, 504c are coupled to respective inputs of the multiplexer 504. The multiplexer 504 is coupled to the integrator portion 506 via the first summing node 506a. The integrator portion 506 is coupled to the multiplier 510 via the second summing node 506b. The target signal input 508 is coupled to the multiplier 510. The multiplier 510 is coupled to the output 512. Within the integrator portion 506 the first summing node 506a is coupled to the second summing node 506b and to the first delay 506c. The first delay 506c is coupled to the first summing node 506a. The second summing node 506b is coupled to the second delay 506d, and the second delay 506d is coupled to the second summing node 506b. The mute control 514 may be coupled to the delay lines 506c, 506d and/or to the select input 502.

The integrator portion 506 is identical to integrator portion 404 of FIG. 4 in some examples. The integrator portion 506 may be of any order. As illustrated, it is third order (having two summing node-delay line pairs), but any number of summing node-delay line pairs may be included in the integrator portion 506. In general, these pairs will be coupled in series with respect to one another. In some examples, the integrator portion 506 is connected to the mute control 514. The mute control 514 may provide a control signal to the delay lines 506c, 506d that force the delay lines 506c, 506d to deactivate or provide a forced values to the summing nodes 506a, 506b. For example, the mute control 514 may force the integrator portion 506, via the delay lines 506c, 506d, to generate an output window function that is all zeroes. Thus, when the window function is provided to the multiplier 510, the output of the multiplier 510 may also be all zeroes (e.g., inaudible in the context of an audio application, though such a window function may have other effects in other types of applications).

The select input 502 provides a control signal to the multiplexer 504 which determines which of the inputs 504a, 504b, 504c the multiplexer 504 will forward to the integrator portion 506. Each input 504a, 504b, 504c represents a different potential voltage (or value) the multiplexer 504 can forward to the integrator portion 506 at any given time. The first input 504a may correspond to a high value or voltage (e.g., “1”), the second input 504b may correspond to a zero or near zero value or voltage (e.g., “0”), and the third input 504c may correspond to a low value or voltage (e.g., “−1”). Thus, the select input 502 may be programmed or configured to control the multiplexer 504 to provide an input signal to the integrator portion 506 that reflects an impulse, for example, as modified by the differentiator portion and rate adjustor of a CIC filter configured as an interpolator (e.g., the delay lines 204, 208 and summing nodes 206, 210 on the input side of the rate adjustor 212 and the rate adjustor 212 of FIG. 2—note that, in FIGS. 1A and 1B the differentiators are on the output side of the rate adjustor). In some examples, the select input 502 may be controlled by the mute control 514. In such examples, the mute control 514 may selectively force the select input 502 to control the multiplexer 504 to generate a predetermined value or sequence of values (rather than a signal corresponding to an impulse). For example, the mute control 514 can, in some examples, force the multiplexer 504 to output only zeroes, thus causing the integrator portion 506 to output a signal that is just the sum of zeroes (and is therefore a zero function). In some examples, when the mute control 514 operates in this manner, it may be to mute (e.g., attenuate to the point of inaudibility or eliminate) the target signal when the target signal is multiplied with the window function.

The target signal input 508 receives and provides or generates a target signal, such as an audio signal, and provides that target signal to the multiplier 510.

The multiplier 510 receives the window function generated by the select input 502, multiplexer 504, and/or integrator portion 506, and multiplies that window function with the target signal. The multiplier 510 provides the resulting output signal to the output 512, where the output signal may be used for any purpose (for example, in generating a Fourier Transformation of the target signal).

In some examples, the select input 502, multiplexer 504, and/or multiplexer inputs 504a, 504b, 504c may be part of or correspond to the input generator 402 of FIG. 4.

As mentioned above, various options are available to alter the behavior of the integrator and/or CIC filter when generating a window function. In examples that include a differentiator portion, the first differentiator (e.g., the first summing node and first delay pair that corresponds to the differentiator) is redundant and may be eliminated. To accomplish this, the rate adjustor may simply provide its output to the second delay as a reset control signal that forces the second delay to output a zero under desired circumstances.

In some examples, bit-pruning may be utilized to reduce the number of bits differentiated or integrated during processing. This is done by determining the number of output bits necessary, and then eliminating bits that are not needed. For example, the connections between the summing nodes in examples herein may be 32 bits (e.g., 32 wire connections on the line), but if the output will never exceed 20 bits, bits may be pruned and the number of wire connections reduced as appropriate.

In some examples, integrators may be replaced with delaying integrators. In delaying integrators, the summing node is not connected to the next summing node and/or integrator in the series. Instead, the summing node connects to the delay, and the delay connects back to the summing node and forward to the next summing node or the rate adjustor. By mixing and/or replacing some (not necessarily all) integrators with delaying integrators, the timing characteristics of the circuit may be manipulated. For example, the impulse response of the circuit may be delayed by up to one cycle (in some examples, one cycle per delaying integrator) without changing the frequency response of the filter.

In examples utilizing a differentiator, the delay may be increased. This adds additional zeroes between the current zeroes of the response function of the CIC filter.

In some examples, only the hardware corresponding to the highest order filter is used, thereby providing area and power savings. This generally applies when cascading CIC filters are used in series.

In some examples, one section of the CIC filter may have (R+n) summing node-delay pairs, where R is the order and/or intended order of the filter, and n is any integer value greater than or equal to one.

In some examples, a finite impulse response (FIR) filter may be added following the output of the filter to compensate for droop (attenuation) in the passband of the filter.

In some examples, minimal memory may be used to hold the predetermined output of the differentiator portion and rate adjustor that is used as an input to the integrator portion (e.g., of FIGS. 3-5). Because the number of coefficients (e.g., the input to the integrator portion) may be relatively small (e.g., less than 10, less than 20, less than 60, and so forth), a like number of registers may be used to store those values, as opposed to allocating large amounts of memory. Furthermore, in some examples, half the coefficients may be stored instead (thus halving the memory requirement, if memory is used) because, in some examples, the inputs to the integrator portion are symmetric. That is, if the input is the sequence (1, 0, −1, −1, 0, 1) you only need to store the first three values, (1, 0, −1) because the order of the values may simply be reversed to obtain the latter half of the input sequence (−1, 0, 1).

It will be understood that the term “sum” refers to any sum produced using addition or subtraction (i.e., the addition of negative values), and any sequence of additions and subtractions used to produce a given value. As a result, a summing node may sum (e.g., combine) two or more voltages together to produce an output voltage. The same may be done with current.

Examples of the methods and systems discussed herein are not limited in application to the details of construction and the arrangement of components set forth in the description or illustrated in the accompanying drawings. The methods and systems are capable of implementation in other embodiments and of being practiced or of being carried out in various ways. Examples of specific implementations are provided herein for illustrative purposes only and are not intended to be limiting. In particular, acts, components, elements and features discussed in connection with any one or more examples are not intended to be excluded from a similar role in any other examples.

Also, the phraseology and terminology used herein is for the purpose of description and should not be regarded as limiting. Any references to examples, embodiments, components, elements or acts of the systems and methods herein referred to in the singular may also embrace embodiments including a plurality, and any references in plural to any embodiment, component, element or act herein may also embrace embodiments including only a singularity. References in the singular or plural form are not intended to limit the presently disclosed systems or methods, their components, acts, or elements. The use herein of “including,” “comprising,” “having,” “containing,” “involving,” and variations thereof is meant to encompass the items listed thereafter and equivalents thereof as well as additional items.

References to “or” may be construed as inclusive so that any terms described using “or” may indicate any of a single, more than one, and all of the described terms. In addition, in the event of inconsistent usages of terms between this document and documents incorporated herein by reference, the term usage in the incorporated features is supplementary to that of this document; for irreconcilable differences, the term usage in this document controls.

Various types or quantities of controllers may execute various operations discussed above. Using data stored in associated memory and/or storage, the controller also executes one or more instructions stored on one or more non-transitory computer-readable media, which the controller may include and/or be coupled to, that may result in manipulated data. In some examples, the controller may include one or more processors or other types of controllers. In one example, the controller is or includes at least one processor. In another example, the controller performs at least a portion of the operations discussed above using an application-specific integrated circuit tailored to perform particular operations in addition to, or in lieu of, a general-purpose processor. Possible controllers include ASICs, FPGAs, MCUs, MPUs, and so forth, though any hardware combination capable of controlling switching devices may be sufficient. As illustrated by these examples, examples in accordance with the present disclosure may perform the operations described herein using many specific combinations of hardware and software and the disclosure is not limited to any particular combination of hardware and software components. Examples of the disclosure may include a computer-program product configured to execute methods, processes, and/or operations discussed above. The computer-program product may be, or include, one or more controllers and/or processors configured to execute instructions to perform methods, processes, and/or operations discussed above.

Having thus described several aspects of at least one embodiment, it is to be appreciated various alterations, modifications, and improvements will readily occur to those skilled in the art. Such alterations, modifications, and improvements are intended to be part of, and within the spirit and scope of, this disclosure. Accordingly, the foregoing description and drawings are by way of example only.

What is claimed is:

1. A window function generating system comprising:
a first node;
a second node;
an integrator portion coupled to the first node;
a differentiator portion coupled to the second node; and
a rate adjustor coupled to the integrator portion and to the differentiator portion.

2. The system of claim 1 further comprising a multiplier coupled to the second node and to an input node, the multiplier being configured to receive an input signal from the input node and a window function signal from the second node and to produce an output signal based on the input signal and window function signal.

3. The system of claim 1 wherein the rate adjustor is a decimator.

4. The system of claim 1 wherein the second node is coupled to the integrator portion.

5. The system of claim 1 wherein the first node is coupled to the differentiator portion.

6. The system of claim 1 wherein the integrator portion includes a plurality of integrator elements, each integrator element including a respective summing node and a respective delay, wherein the respective summing node of an integrator element is coupled to the respective delay of the integrator element at an input and an output of the delay.

7. The system of claim 6 wherein the respective summing node of the integrator element is coupled to at least one other summing node of a different integrator element.

8. The system of claim 7 wherein at least one summing node of the integrator portion is coupled to the rate adjustor.

9. The system of claim 1 wherein the differentiator portion includes a plurality of differentiator elements, each differentiator element including a respective summing node and a respective delay, wherein the respective delay of a differentiator element is coupled to the respective summing node of the differentiator element at an input of the summing node.

10. The system of claim 9 wherein the respective summing node of the differentiator element is coupled to at least one other summing node of a different differentiator element.

11. The system of claim 10 wherein at least one summing node of the differentiator portion is coupled to the rate adjustor.

12. The system of claim 1 wherein the first node is one of an output or an input, and the second node is the other of the output or input.

13. A window function generating system comprising:
an input generator;
an integrator portion coupled to the input generator, the input generator selectively providing one of at least two or more different output levels to the integrator portion; and
an output coupled to the integrator portion, the input generator being configured to provide a sequence of values to the integrator portion, the sequence of values being a predetermined sequence made up of three distinct values.

14. The system of claim 13 wherein the three distinct values correspond to −1, 0, and 1.

15. The system of claim 14 wherein each value of the three distinct values corresponds to a respective distinct voltage level.

16. The system of claim 14 wherein the integrator portion includes at least a first summing node coupled to a first delay at an input and an output of the first delay, and wherein the integrator portion includes at least a second summing node coupled to a second delay at an input and an output of the second delay.

17. The system of claim 16 wherein a first summing node produces a first summed output based on a value from the input generator summed together with a first delayed value from the first delay, and provides the first summed output to the second summing node and to the first delay; and
wherein the second summing node produces a second summed output based on the first summed output and a second delayed value from the second delay, and provides the second summed output to the output coupled to the integrator portion.

18. The system of claim 14 wherein the input generator includes a multiplexer configured to select between values of the sequence of values, and a select generator configured to control the multiplexer to determine which value of the sequence of values is provided to the integrator portion.

19. The system of claim 14 further comprising a mute control coupled to delay lines of the integrator portion and configured to provide a signal to the input generator to force the input generator to provide a 0 to the integrator portion.

20. The system of claim 13 further comprising a multiplier and a target signal input, the target signal input being coupled to the multiplier and configured to provide a target signal to the multiplier, and the multiplier being configured to multiply an output of the integrator with the target signal to produce a processed signal.
